(19) United States
(12) Patent Application Publication
(10) Pub. No.: US 2026/0164761 A1
(43) Pub. Date: Jun. 11, 2026

(54) FABRICATING METHOD OF LOW VOLTAGE TRANSISTOR, MIDDLE VOLTAGE TRANSISTOR, AND HIGH VOLTAGE TRANSISTOR

(71) Applicant: United Semiconductor (Xiamen) Co., Ltd., Xiamen (CN)

(72) Inventors: Jian Liu, Xiamen (CN); Chen Chen, Singapore (SG); Jinjian Ouyang, Xiamen (CN); Chin-Chun Huang, Hsinchu County (TW); Wen Yi Tan, Xiamen (CN)

(73) Assignee: United Semiconductor (Xiamen) Co., Ltd., Xiamen (CN)

(21) Appl. No.: 19/007,572

(22) Filed: Jan. 2, 2025

(30) Foreign Application Priority Data
Dec. 9, 2024 (CN) 202411794792.4

(51) Int. Cl. H10D 84/01

(52) U.S. Cl. CPC H10D 84/0144; H10D 84/013; H10D 84/0142; H10D 84/0151

(57) ABSTRACT

A fabricating method of low voltage, middle voltage and high voltage transistors includes providing a substrate. A first active region, a second active region and a third active region are respectively disposed in a low voltage region, a middle voltage region and a high voltage region. Two second source/drain regions is embedded in the second active region. Two third source/drain regions are disposed in the third active region. A middle voltage gate dielectric material layer is formed to cover the first active region, the second active region and the two third source/drain regions. Later, a patterned mask is formed to expose all the middle voltage gate dielectric material layer disposed in the first active region, on the two second source/drain regions, and on the two third source/drain regions. Next, the exposed middle voltage gate dielectric material layer is removed completely by taking the patterned mask as a mask.

### BACKGROUND OF THE INVENTION

### 1. Field of the Invention

The present invention relates to a fabricating method of a low voltage transistor, a middle voltage transistor and a high voltage transistor, and in particular to a fabricating method of a low voltage transistor, a middle voltage transistor and a high voltage transistor that reduces process steps.

### 2. Description of the Prior Art

Transistor is one of the most important components in integrated circuits. Its function determines the quality of the electrical circuits. It is an important technical indicator in today's semiconductor industry. Taking the MOS transistors as an example, when different bias voltages are applied to the gate, the current between the source and drain can be turned on or off.

MOS transistors are divided into low voltage, middle voltage and high voltage according to the operating range. Low voltage transistors, middle voltage transistors and high voltage transistors can serve as elements to form switches or amplifier circuits.

Because high voltage transistors are applied with high voltages, generally above 500 volts, high voltage transistors need to have a higher breakdown voltage to withstand high input voltages. Compared with high voltage transistors, middle voltage transistors have a lower operating voltage, generally between ten to hundreds of volts, and are mainly used in middle power ranges. The operating voltage of low voltage transistors is generally below 40 volts.

As the size of electronic products shrinks, it is necessary to integrate multiple components on a single chip, so that more components can be placed on the limited chip area, thereby making the integrated chip functions more powerful.

### SUMMARY OF THE INVENTION

In view of this, the present invention provides a fabricating method that integrates high voltage, middle voltage and low voltage transistors.

According to a preferred embodiment of the present invention, a fabricating method of a low voltage transistor, a middle voltage transistor and a high voltage transistor includes providing a substrate, wherein the substrate includes a low voltage region, a middle voltage region and a high voltage region, wherein a first active region is disposed in the low voltage region, a second active region is disposed in the middle voltage region, two second source/drain regions are embedded in the second active region, a third active region is disposed in the high voltage region, a high voltage gate dielectric layer is embedded in the third active region, two third source/drain regions are disposed in the third active region at two sides of the high voltage gate dielectric layer. Next, a middle voltage gate dielectric material layer is formed to cover an entirety of the first active region, an entirety of the second active region and the two third source/drain regions. Later, a patterned mask is formed to cover part of the middle voltage gate dielectric material layer within the second active region to expose all of the middle voltage gate dielectric material layer within the first active region, the middle voltage gate dielectric material layer on the two second source/drain regions, and the middle voltage gate dielectric material layer on the two third source/drain regions. Subsequently, the middle voltage gate dielectric material layer which is exposed is completely removed by taking the patterned mask as a mask, wherein the middle voltage gate dielectric material layer which remains severs as a middle voltage gate dielectric layer. After removing the middle voltage gate dielectric material layer, a first gate structure, a second gate structure and a third gate structure are formed, wherein the first gate structure is disposed on the first active region, the second gate structure is disposed on the middle voltage gate dielectric layer, and the third gate structure is disposed on the high voltage gate dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 depict a fabricating method of a low voltage transistor, a middle voltage transistor and a high voltage transistor according to a preferred embodiment of the present invention, wherein:

FIG. 2 is a fabricating stage in continuous of FIG. 1;

FIG. 3 is a fabricating stage in continuous of FIG. 2; and

FIG. 4 is a fabricating stage in continuous of FIG. 3.

### DETAILED DESCRIPTION

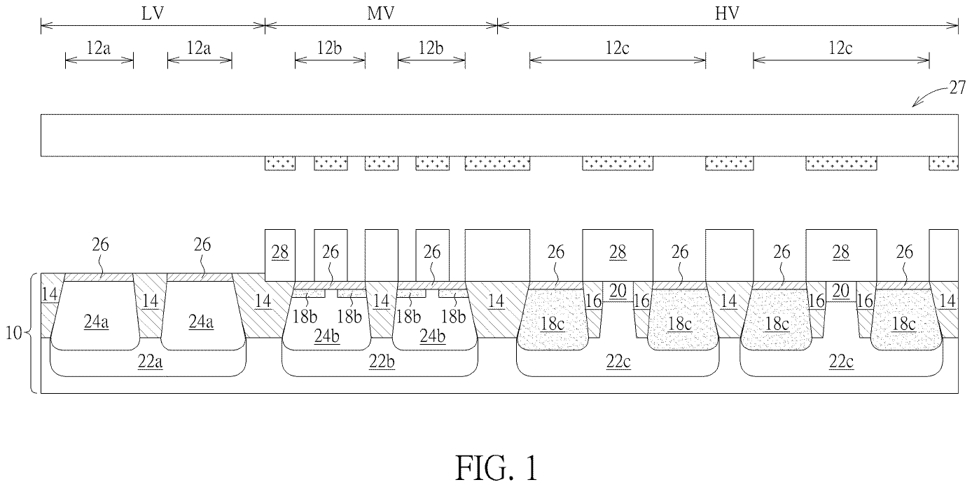

FIG. 1 to FIG. 4 depict a fabricating method of a low voltage transistor, a middle voltage transistor and a high voltage transistor according to a preferred embodiment of the present invention.

As shown in FIG. 1, a substrate 10 is provided. The substrate 10 includes a low voltage region LV, a middle voltage region MV, and a high voltage region HV. A first active region 12a is disposed in the low voltage region LV, a second active region 12b is disposed in the middle voltage region MV, and a third active region 12c is disposed in the high voltage region HV. The first active region 12a is used for setting low voltage transistors, the second active region 12b is used for setting middle voltage transistors, and the third active region 12c is used for setting high voltage transistors. Based on different product requirements, there can be more than one first active regions 12a in the low voltage region LV, more than one second active regions 12b in the middle voltage region MV, and more than one third active regions 12c in the high voltage region HV.

Moreover, numerous shallow trench isolations 14 are embedded in the substrate 10 to separate the first active region 12a, the second active region 12b and the third active region 12c. Two second source/drain regions 18b are embedded in the second active region 12b. A high voltage gate dielectric layer 20 is embedded in the third active region 12c. Two third source/drain regions 18c are respectively disposed in the third active region 12c at two sides of the high voltage gate dielectric layer 20. According to a preferred embodiment of the present invention, the second source/drain regions 18b and the third source/drain regions 18c are doping regions formed by using an ion implantation process.

Two shallow trench isolations 16 are also embedded in the third active region 12c and a high voltage gate dielectric layer 20 is disposed between the shallow trench isolations 16. A first deep doping well 22a, a second deep doping well 22b, and a third deep doping well 22c are respectively disposed in the first active region 12a, the second active region 12b, and the third active region 12c. Furthermore, a first doping well 24a and a second doping well 24b are respectively disposed in the first deep doping well 22a and the second deep doping well 22b.

Later, a middle voltage gate dielectric material layer 26 is formed to cover all of the first active region 12a, all of the second active region 12b and the third source/drain regions 18c. The middle voltage gate dielectric material layer 26 includes silicon oxide, silicon nitride, silicon oxynitride or other insulating materials. In this embodiment, the middle voltage gate dielectric material layer 26 is preferably silicon oxide. Later, a photomask 27 is used to form a patterned mask 28 through an exposure and development process. The patterned mask 28 covers part of the middle voltage gate dielectric material layer 26 in the second active region 12b, the shallow trench isolations 14/16 in the middle voltage region MV and the high voltage region HV and the high voltage gate dielectric layer 20. The patterned mask 28 is preferably photoresist. All of the middle voltage gate dielectric material layer 26 in the first active region 12a, the middle voltage gate dielectric material layer 26 on the second source/drain regions 18b, the middle voltage gate dielectric material layer 26 on the third source/drain regions 18c, and the shallow trench isolation 14 in low voltage region LV are exposed through the patterned mask 28. Now, the top surface of the shallow trench isolation 14 in the low voltage region LV is higher than the top surface of the shallow trench isolation 14 in the middle voltage region MV and in the high voltage region HV.

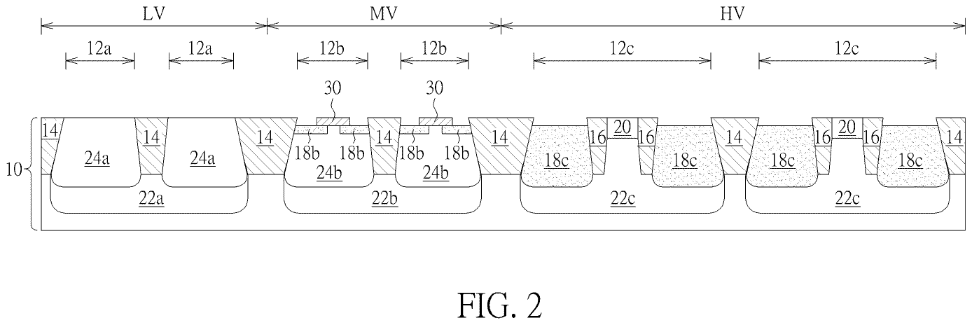

As shown in FIG. 2, an etching process is performed by taking the patterned mask 28 as a mask to completely remove the exposed middle voltage gate dielectric material layer 26. The middle voltage gate dielectric material layer 26 which remains serves as a middle voltage gate dielectric layer 30. In details, after the etching process, only part of the middle voltage gate dielectric material layer 26 in the middle voltage region MV is remained, and the middle voltage gate dielectric material layer 26 outside of the middle voltage region MV is completely removed. Moreover, the shallow trench isolation 14 in the low voltage region LV is also partially removed therefore the top surface of shallow trench isolation 14 in the low voltage region LV is reduced. In this way, the top surface of the shallow trench isolation 14 in the low voltage region LV is aligned with the top surface of the shallow trench isolation 14 in the middle voltage region MV and the high voltage region HV. The etching process can be a dry etching or a wet etching. In this embodiment, a wet etching is preferably used, and the etchant is preferably hydrofluoric acid solution.

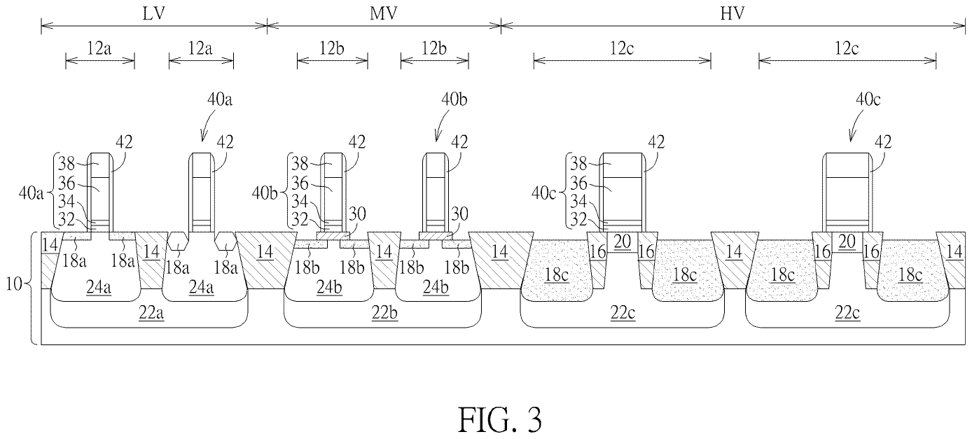

As shown in FIG. 3, a first gate structure 40a, a second gate structure 40b and a third gate structure 40c are formed. The first gate structure 40a is disposed on the first active region 12a, the second gate structure 40b is disposed on the middle voltage gate dielectric layer 30, and the third gate structure 40c is disposed on the high voltage gate dielectric layer 20. In details, fabricating steps of the first gate structure 40a, the second gate structure 40b and the third gate structure 40c includes forming a silicon oxide layer 32, a high dielectric constant layer 34, a polysilicon layer 36 and a cap layer 38 in sequence to blankly cover the low voltage region LV, the middle voltage region MV and the high voltage region HV. The silicon oxide layer 32, the high dielectric constant layer 34, the polysilicon layer 36 and the cap layer 38 are preferably formed by using deposition processes.

After that, the cap layer 38, the polysilicon layer 36, the high dielectric constant layer 34 and the silicon oxide layer 32 are patterned to form the first gate structure 40a, the second gate structure 40b and the third gate structure 40c. The silicon oxide layer 32 and the high dielectric constant layer 34 within the first active region 12a serve as a low voltage gate dielectric layer. Next, liners 42 are respectively formed on two sides of the first gate structure 40a, two sides of the second gate structure 40b, and two sides of the third gate structure 40c. Then, two first source/drain regions 18a are formed in the first active region 12a on two sides of the first gate structure 40a. The first source/drain regions 18a may be doping regions formed by an ion implantation process, or may be doped epitaxial layers formed by an epitaxial process.

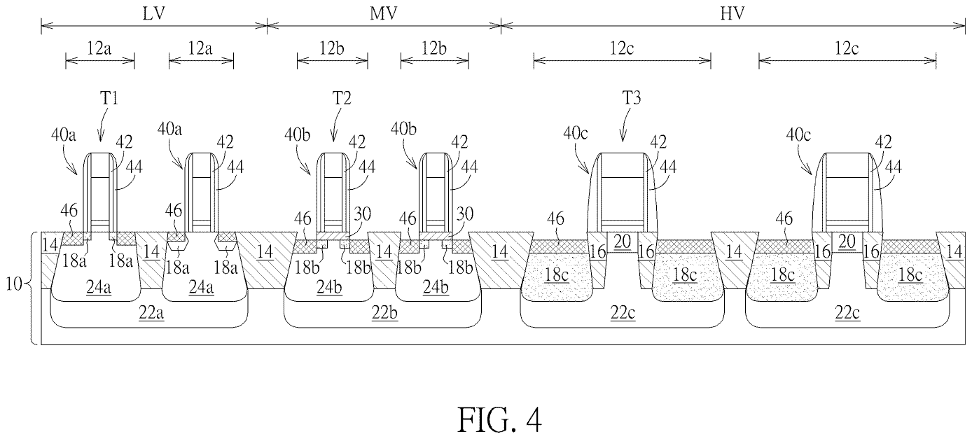

As shown in FIG. 4, spacers 44 are respectively formed at two sides of the first gate structure 40a, two sides of the second gate structure 40b and two sides of the third gate structure 40c. The spacers 44 cover the liner 40. Later, silicides 46 are respectively formed on the first source/drain regions 18a, the second source/drain regions 18b and the third source/drain regions 18c. The first deep doping well 22a, the first doping well 24a, the first gate structure 40a, the liner 42, the spacers 44, the first source/drain regions 18a and the silicides 46 together form a low voltage transistor T1. The second deep doping well 22b, the second doping well 24b, the second gate structure 40b, the liner 42, the spacers 44, the second source/drain regions 18b and the silicides 46 together form a middle voltage transistor T2. The third deep doping well 22c, the third gate structure 40c, the third source/drain regions 18c, the liner 42, the spacers 44 and the silicides 46 together form a high voltage transistor T3. At this point, the low voltage transistor T1, the middle voltage transistor T2 and the high voltage transistor T3 of the present invention are completed. Based on the conductive types of the low voltage transistor T1, the middle voltage transistor T2 and the high voltage transistor T3, the first source/drain regions 18a, the second source/drain regions 18b, the third source/drain regions 18c, the first deep doping well 22a, the second deep doping well 22b, the third deep doping well 22c, the first doping well 24a, and the second doping well 24b may respectively be of N-type or P-type.

Furthermore, based on product requirements, after the first gate structure 40a, the second gate structure 40b and the third gate structure 40c are completed, a metal gate process can be performed to replace the polysilicon layer 36 by metal gates.

The middle voltage transistor, the low voltage transistor and the high voltage transistor have corresponding gate dielectric layers. In the process of the present invention, the high voltage gate dielectric layer of the high voltage transistor is formed first. Later, the middle voltage gate dielectric layer of the middle voltage transistor is formed. The low voltage gate dielectric layer of the low voltage transistor is formed last. The process of forming the middle voltage gate dielectric layer of the middle voltage transistor includes simultaneously forming the middle voltage gate dielectric material layer on the entire first active region (low voltage), the entire second active region (middle voltage), and on the source/drain regions within the third active region (high voltage). In order to form the low voltage gate dielectric layer of the low voltage transistor, to form the source/drain regions of the middle voltage transistor, and to form the source/drain regions of the high voltage transistor, the middle voltage gate dielectric material layer on the first active region, on the source/drain regions within the second active region, and on the source/drain regions within the third active region are removed. In the conventional process, the middle voltage gate dielectric material layer on the first active region, on the source/drain regions within the second active region, and on the source/drain regions within the third active regions is removed independently by using different photomasks. However, the present invention uses the same photomask to perform the step of removing the middle voltage gate dielectric material layer in one removing step, thereby the manufacturing process is simplified and/or production cost is reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fabricating method of a low voltage transistor, a middle voltage transistor and a high voltage transistor, comprising:
providing a substrate, wherein the substrate comprises a low voltage region, a middle voltage region and a high voltage region, and wherein a first active region is disposed in the low voltage region, a second active region is disposed in the middle voltage region, two second source/drain regions are embedded in the second active region, a third active region is disposed in the high voltage region, a high voltage gate dielectric layer is embedded in the third active region, and two third source/drain regions are disposed in the third active region at two sides of the high voltage gate dielectric layer;
forming a middle voltage gate dielectric material layer to cover an entirety of the first active region, an entirety of the second active region and the two third source/drain regions;
forming a patterned mask to cover part of the middle voltage gate dielectric material layer within the second active region to expose an entirety of the middle voltage gate dielectric material layer within the first active region, to expose the middle voltage gate dielectric material layer on the two second source/drain regions, and to expose the middle voltage gate dielectric material layer on the two third source/drain regions;
completely removing the middle voltage gate dielectric material layer which is exposed by taking the patterned mask as a mask, wherein the middle voltage gate dielectric material layer which remains severs as a middle voltage gate dielectric layer; and
after removing the middle voltage gate dielectric material layer, forming a first gate structure, a second gate structure and a third gate structure, wherein the first gate structure is disposed on the first active region, the second gate structure is disposed on the middle voltage gate dielectric layer, and the third gate structure is disposed on the high voltage gate dielectric layer.

2. The fabricating method of a low voltage transistor, a middle voltage transistor and a high voltage transistor of claim 1, wherein two second source/drain regions are respectively disposed in the second active region at two sides of the middle voltage gate dielectric layer.

3. The fabricating method of a low voltage transistor, a middle voltage transistor and a high voltage transistor of claim 1, wherein fabricating steps of the first gate structure, the second gate structure and the third gate structure comprise:
forming a silicon oxide layer, a high dielectric constant layer, a polysilicon layer and a cap layer in sequence to blankly cover the low voltage region, the middle voltage region and the high voltage region; and
patterning the cap layer, the polysilicon layer, the high dielectric constant layer and the silicon oxide layer to form the first gate structure, the second gate structure and the third gate structure.

4. The fabricating method of a low voltage transistor, a middle voltage transistor and a high voltage transistor of claim 1, further comprising:
after forming the first gate structure, forming two first source/drain regions in the first active region at two sides of the first gate structure.

5. The fabricating method of a low voltage transistor, a middle voltage transistor and a high voltage transistor of claim 1, further comprising a first shallow trench isolation and a second shallow trench isolation, wherein the first shallow trench isolation is embedded in the low voltage region, the second shallow trench isolation is embedded in the middle voltage region, and a top surface of the first shallow trench isolation is aligned with a top surface of the second shallow trench isolation.
